(19) United States
(12) Patent Application Publication
(10) Pub. No.: US 2025/0232778 A1
(43) Pub. Date: Jul. 17, 2025

(54) TRANSMISSION APPARATUS, RECEPTION APPARATUS, AND TRANSCEPTION SYSTEM

(71) Applicant: SONY GROUP CORPORATION, TOKYO (JP)

(72) Inventor: KAZUO YAMAMOTO, TOKYO (JP)

(21) Appl. No.: 18/848,535

(22) PCT Filed: Mar. 2, 2023
(86) PCT No.: PCT/JP2023/007749

§ 371 Date: Sep. 19, 2024

(30) Foreign Application Priority Data
Mar. 30, 2022 (JP) 2022-055281

(51) Int. Cl. G10L 19/002

(52) U.S. Cl. CPC G10L 19/002

(57) ABSTRACT

To transmit a vibration signal in such a manner that arithmetic operation processing can favorably be executed on a reception side. The vibration signal is converted into data in floating-point format by a conversion section. For example, the vibration signal is an audio signal or a tactile vibration signal. For example, the data in the floating-point format is 16-bit half-precision floating-point data. The data in the floating-point format is transmitted by a transmission section to an external apparatus via a transmission path. For example, the transmission path is an HDMI transmission path. Moreover, for example, the transmission section uses a transmission signal structure for each block including a plurality of frames for an audio signal to transmit the data in the floating-point format.

### TECHNICAL FIELD

The present technology relates to a transmission apparatus, a reception apparatus, and a transception system and particularly to a transmission apparatus and the like which transmit a vibration signal to an external apparatus via a transmission path such that complicated arithmetic operation processing can favorably be executed on a reception side.

### BACKGROUND ART

It has been considered that, for example, object audio data including sound data and position data relating to a sound source is transmitted from a transmission side and sound reproduction increased in realistic surrounding effect is executed on a reception side. Moreover, it has been considered that a tactile vibration signal is transmitted as a haptics signal from the transmission side and a tactile stimulus is provided to a user on the reception side.

In this case, regarding the object audio data, arithmetic operation processing of distributing the sound of the sound source to each of multiple speakers disposed in a space is applied on the reception side on the basis of the position of the sound source. Moreover, regarding the tactile vibration signal, arithmetic operation processing of adjusting a gain according to sensitivity of each user, sensitivity of a portion to be stimulated, sensitivity of the vibration device, and further nonlinearity of the vibration device is applied on the reception side.

For example, in PTL 1, there is disclosed an increase in efficiency by dividing processing into processing for an exponent part and processing for a fraction part when data in floating-point format is compressed.

### CITATION LIST

### Patent Literature

### [PTL 1]

Japanese Patent Laid-open No. 2018-037891

### SUMMARY

### Technical Problem

In order to maintain a high precision even when the arithmetic operation processing is executed on the reception side as described above, it is required to transmit the vibration signal (the sound data relating to the sound source, the tactile vibration signal as the haptics signal, and the like in the object audio data) in a signal format appropriate for the arithmetic operation processing from the transmission side.

An object of the present technology is to transmit a vibration signal in such a manner that arithmetic operation processing can favorably be executed on a reception side.

### Solution to Problem

A concept of the present technology is in a transmission apparatus including a conversion section that converts a vibration signal into data in floating-point format, and a transmission section that transmits the data in the floating-point format to an external apparatus via a transmission path.

In the present technology, the vibration signal is converted into the data in the floating-point format by the conversion section. For example, the vibration signal may be an audio signal or a tactile vibration signal. Moreover, for example, the data in the floating-point format may be 16-bit half-precision floating-point (binary16) data. With this configuration, the data in the floating-point format can express a range of value from −65504 to 65504 and has a 11-bit precision.

Moreover, for example, the conversion section may set a maximum displacement of the vibration signal to a predetermined value smaller than a maximum value of a range of a value determined by the number of bits of an exponent part of the data in the floating-point format, for example, 1, thereby converting the vibration signal into the data in the floating-point format. With this configuration, even when an arithmetic operation for the data in the floating-point format is continued on the reception side, the range of the value has a margin, and hence, an arithmetic operation of handling a signal exceeding the maximum displacement (100%) of the vibration signal can be executed.

The data in the floating-point format is transmitted by the transmission section to an external apparatus via the transmission path. For example, the transmission path may be an HDMI transmission path. Moreover, for example, the transmission section may use a transmission signal structure for each block including a plurality of frames for an audio signal to transmit the data in the floating-point format. With this configuration, the data in the floating-point format obtained by converting the vibration signal can favorably be transmitted to the external apparatus.

In this case, for example, the transmission signal structure may be a frame structure of the IEC 60958 standard and the transmission section may dispose the data in the floating-point format in a region for the Audio sample word or regions for the Audio sample word and the Auxiliary sample bits and transmit the data in the floating-point format. Moreover, in this case, the data in the floating-point format may be disposed in an order of a sign part, an exponent part, and a fraction part from a most significant bit side of the Audio sample word without a space, in the region for the Audio sample word or the regions for the Audio sample word and the Auxiliary sample bits. In this configuration, the exponent part in the data in the floating-point format may include 5 bits, the fraction part may include 10 bits, 14 bits, or 18 bits.

As a result of the disposition from the most significant bit side without a space, when, for example, as the data in the floating-point format, the data the number of bits of the exponent part of which is not changed and only the number of bits of the fraction part of which is increased for increasing the precision is transmitted and even when the reception side erroneously handles this data while assuming that data in floating-point format having the smaller number of bits in the fraction part is disposed, only the precision decreases, and a failure can be avoided.

For example, the Channel status provided in the transmission signal structure for each block may include information indicating that the data in the floating-point format is disposed in the region for the Audio sample word or the regions for the Audio sample word and the Auxiliary sample bits. With this configuration, it is possible for the reception side to easily recognize that the data in the floating-point format is disposed in the region for the Audio sample word or the regions for the Audio sample word and the Auxiliary sample bits.

Moreover, in this case, for example, the Channel status provided in the transmission signal structure for each block may include information indicating the number of bits of the data in the floating-point format disposed in the region for the Audio sample word or the regions for the Audio sample word and the Auxiliary sample bits. With this configuration, it is possible for the reception side to easily recognize the number of bits of the data in the floating-point format disposed in the region for the Audio sample word or the regions for the Audio sample word and the Auxiliary sample bits.

Moreover, for example, the transmission section may apply, when the sign part indicates a negative sign, bit inversion processing to the exponent part, and then may transmit the data in the floating-point format. With this configuration, even when the data in the floating-point format is erroneously recognized as data in signed integer format on the reception side, it is possible to suppress a sharp waveform fluctuation at the time of zero cross and an unbalanced DC component.

Moreover, for example, the transmission section may apply, when a sign part of the data in the floating-point format indicates the negative sign, bit inversion processing to an exponent part and perform processing of converting a fraction part to a two's complement number, and may then transmit the data in the floating-point format. With this configuration, even when the data in the floating-point format is erroneously recognized as data in signed integer format on the reception side, it is possible to suppress a sharp waveform fluctuation at the time of zero cross and an unbalanced DC component. In this case, a waveform at the time of a negative value can be clean by applying not only the bit inversion processing to the exponent part, but also applying the processing of converting the fraction part into the two's complement, compared with the case in which only the bit inversion processing is applied to the exponent part.

As described above, in the present technology, the vibration signal is converted into the data in the floating-point format, this data in the floating-point format is transmitted to the external apparatus via the transmission path, and hence, complicated arithmetic operation processing applied to the vibration signal can favorably be executed in the external apparatus.

Moreover, another concept of the present technology is in a reception apparatus including a reception section that receives, from an external apparatus via a transmission path, data in floating-point format obtained by converting a vibration signal, and a processing section that processes the data in the floating-point format.

Moreover, another concept of the present technology is in a transception system, in which a transmission apparatus and a reception apparatus are connected to each other via a transmission path, the transmission apparatus includes a conversion section that converts a vibration signal into data in floating-point format, and a transmission section that transmits the data in the floating-point format to the reception apparatus via the transmission path, and the reception apparatus includes a reception section that receives the data in the floating-point format from the transmission apparatus via the transmission path, and a processing section that processes the data in the floating-point format.

### BRIEF DESCRIPTION OF DRAWINGS

FIG. 1 is a block diagram for illustrating a configuration example of a transception system as a first embodiment.

FIG. 2 is a diagram for illustrating a frame structure of the IEC 60958 standard.

FIG. 3 is a diagram for illustrating a sub-frame structure of the IEC 60958 standard.

FIG. 4 is a diagram for illustrating a configuration of binary 16-bit data.

FIG. 5 is a diagram for illustrating a frame configuration in an audio stream having the frame structure of the IEC 60958 standard.

FIG. 6 depicts diagrams for describing binary 16-bit data (binary16) in comparison with a signed integer 16-bit data (signed int16).

FIG. 7 is a drawing for illustrating a case in which the signed integer 16-bit data (signed int16) and the binary 16-bit data (binary16) are applied to an audio signal.

FIG. 8 is a table for schematically illustrating a format of the Channel status in the IEC 60958 standard.

FIG. 9 is a table for illustrating an example of a definition of “b” of a 1st bit of a 0th byte and “d” of a 3rd bit to a 5th bit of the 0th byte in the Channel status.

FIG. 10 is a table for illustrating another example of the definition of “b” in the 1st bit of the 0th byte and “d” in the 3rd bit to the 5th bit of the 0th byte in the Channel status.

FIG. 11 is a table for illustrating an example of a definition of “Word length” and “Sample word length” in the Channel status.

FIG. 12 is a diagram for illustrating a waveform example in a case in which a data string expressing a sine wave having an amplitude of 12.5% (vibrates in a range of −0.125 to +0.125) in the binary 16-bit data (binary16) is mistaken as the signed integer 16-bit data (signed int16).

FIG. 13 is a diagram for describing processing applied to the binary 16-bit data (binary16) in an improvement plan 1.

FIG. 14 is a diagram for illustrating a waveform example in a case in which, in a case in which the data string expressing the sine wave having the amplitude of 12.5% (vibrates in the range of −0.125 to +0.125) in the binary 16-bit data (binary16) is processed through the improvement plan 1, this data string is mistaken as the signed integer 16-bit data (signed int16).

FIG. 15 is a diagram for describing processing applied to the binary 16-bit data (binary16) in an improvement plan 2.

FIG. 16 is a diagram for illustrating a waveform example in a case in which, in a case in which the data string expressing the sine wave having the amplitude of 12.5% (vibrates in the range of −0.125 to +0.125) in the binary 16-bit data (binary16) is processed through an improvement plan 2, this data string is mistaken as the signed integer 16-bit data (signed int16).

FIG. 17 depicts diagrams for describing a case of a sine wave having an amplitude of 50% (vibrates in a range from −0.5 to +0.5).

FIG. 18 depicts diagrams for describing precision improvement for the data in the floating-point format.

FIG. 19 is a diagram for illustrating a disposition example of the frame structure of the IEC 60958 standard in the audio stream in a case in which the binary 20-bit data or the binary 24-bit data is used.

FIG. 20 is a block diagram for illustrating a configuration example of a transception system as a second embodiment.

FIG. 21 is a table for illustrating a packet configuration example of a new InfoFrame including position data relating to a sound source.

FIG. 22 is a block diagram for illustrating a configuration example of a transception system as a third embodiment.

### DESCRIPTION OF EMBODIMENTS

A description is now given of forms for embodying the invention (hereinafter referred to as “embodiments”). Note that the description is given in the following order.
1. First Embodiment
2. Second Embodiment
3. Third Embodiment
4. Modification Example

### 1. First Embodiment

### (Configuration Example of Transception System)

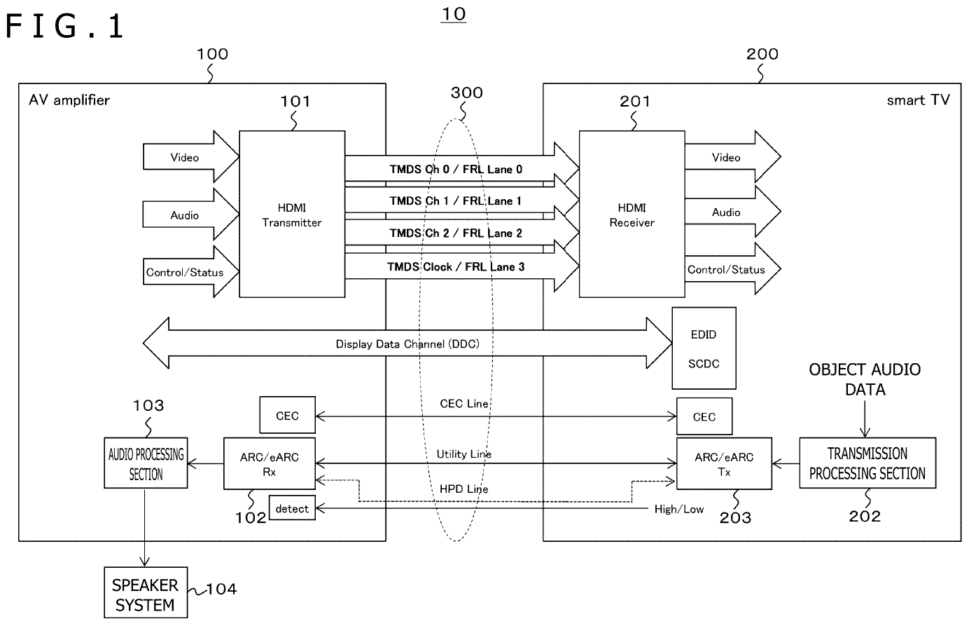

FIG. 1 illustrates a configuration example of a transception system 10 as a first embodiment. This transception system 10 has such a configuration that an AV (Audio/Visual) amplifier 100 as an HDMI (High-Definition Multimedia Interface) source and a smart TV (television) 200 as an HDMI sink are connected to each other via an HDMI cable 300. Note that “HDMI” is a registered trademark.

The AV amplifier 100 transmits, to the smart TV 200 on a plurality of channels, differential signals corresponding to non-compressed pixel data relating to an image for one screen in an effective image period (hereinafter also appropriately referred to as an active video period) being a period obtained by removing a horizontal blanking period and a vertical blanking period from a period from one vertical synchronous signal to a next vertical synchronous signal and transmits, to the smart TV 200 on the plurality of channels, differential signals corresponding to at least audio data and control data accompanying the image, other types of auxiliary data, and the like in the horizontal blanking period or the vertical blanking period.

That is, the AV amplifier 100 includes an HDMI transmitter 101. The HDMI transmitter 101, for example, converts the pixel data relating to the non-compressed image into corresponding differential signals and serially transmits the differential signals on three TMDS channels #0, #1, and #2 being a plurality of channels to the smart TV 200 connected via the HDMI cable 300.

Moreover, the HDMI transmitter 101 converts audio data accompanying the non-compressed image and, further, required control data, other types of auxiliary data, and the like into corresponding differential signals and serially transmits the differential signals on the three TMDS channels #0, #1, and #2 to the smart TV 200 connected via the HDMI cable 300.

Further, the HDMI transmitter 101 transmits a pixel clock synchronized with the pixel data transmitted on the three TMDS channels #0, #1, and #2 on a TMDS clock channel to the smart TV 200 connected via the HDMI cable 300. On one TMDS channel #i (i=0, 1, 2), the pixel data in 10 bits is transmitted during 1 clock of the pixel clock.

In this configuration, TMDS coding is 8-bit/10-bit conversion coding of converting data in 8 bits to data in 10 bits and is coding which reduces transition points in comparison with the previous data to thereby suppress an adverse effect such as unnecessary radiation and which maintains the DC balance. Thus, a run length of the coding cannot theoretically be guaranteed and hence DC coupling, and the independent transmission of the clock are indispensable.

The smart TV 200 receives the differential signals corresponding to the pixel data transmitted from the AV amplifier 100 on the plurality of channels in the active video period and receives the differential signals corresponding to the audio data and the control data transmitted from the AV amplifier 100 on the plurality of channels in the horizontal blanking period or the vertical blanking period.

That is, the smart TV 200 includes an HDMI receiver 201. The HDMI receiver 201 receives the differential signals corresponding to the pixel data and the differential signals corresponding to the audio data and the control data transmitted on the TMDS channels #0, #1, and #2 from the AV amplifier 100 connected via the HDMI cable 300 in synchronism with the pixel clock similarly transmitted on the TMDS clock channel from the AV amplifier 100.

Note that there is described above the example in which the image data, the audio data, and the control data are transmitted on the TMDS channels #0, #1, and #2 and the pixel clock is transmitted on the TMDS clock channel, and this example corresponds to HDMI 1.4 or earlier and HDMI 2.0. In a case of HDMI 2.1, transmission through use of the FRL lanes #0, #1, #2, and #3 is executed. In this case, the TMDS clock channel corresponds to the FRL lane #3.

In this case, the data transmission on fixed rate link (FRL) packets through use of the three lanes #0 to #2 or the four lanes #0 to #3 is executed. In this configuration, FRL Character coding is 16-bit/18-bit conversion coding of converting data in 16 bits into data in 18 bits, is a coding which maintains the DC balance, and is a coding which allows clock extraction.

Moreover, the smart TV 200 transmits object audio data acquired from, for example, an AV streaming service to the AV amplifier 100.

That is, the smart TV 200 includes a transmission processing section 202 and an ARC (Audio Return Channel)/eARC (Enhanced Audio Return Channel) transmission section (ARC/eARC Tx) 203. The transmission processing section 202 inputs the object audio data and generates an audio stream including this object audio data. In this configuration, the object audio data includes sound data (audio signals) and position data relating to a sound source. In this configuration, the sound data (audio signals) constitutes vibration signals. Details of the audio stream are further described later.

The ARC/eARC transmission section 203 transmits the audio stream generated in the transmission processing section 202 to the AV amplifier 100 on an audio return channel or an enhanced audio return channel which uses the Utility Line and the HPD Line of the HDMI cable 300.

The AV amplifier 100 receives the audio stream transmitted on the audio return channel or the enhanced audio return channel from the smart TV 200 and executes rendering processing through use of the object audio data included in this audio stream, thereby generating an audio signal for each speaker included in a speaker system 104.

That is, the AV amplifier 100 includes an ARC/eARC reception section (ARC/eARC Rx) 102 and an audio processing section 103. The ARC/eARC transmission section 102 receives the audio stream transmitted on the audio return channel or the enhanced audio return channel from the smart TV 200.

The audio processing section 103 extracts the object audio data from the audio stream received by the ARC/eARC reception section 102, executes the rendering processing through use of this object audio data, thereby generating the audio signal for each speaker included in the speaker system 104, and supplies the audio signal to the corresponding speaker of the speaker system 104.

Note that transmission channels of the HDMI system include, in addition to the transmission channels for TMDS or FRL described above, transmission channels called DDC (Display Data Channel), and further, CES Line and HPD Line.

The DDC includes two lines (signal lines) which are included in the HDMI cable 300 and are not illustrated. The DDC is used by the AV amplifier 100 to read EDID stored in an EDID ROM (Extended Display Identification ROM) included in the smart TV 200 via the HDMI cable 300. Moreover, the DDC is used by the AV amplifier 100 to perform reading and writing of data relating to SCDCS stored in an SCDC (Status and Control Data Channel) register included in the smart TV 200 via the HDMI cable 300.

Moreover, the CEC line is used for bidirectional communication of data for control between the AV amplifier 100 and the smart TV 200. The HPD line is used by the AV amplifier 100 to detect the connection of the smart TV 200 and the like.

### “Details of Audio Stream”

A description is now given of the details of the audio stream generated by the object audio data processing section 202 of the smart TV 200. The transmission processing section 202 generates the audio stream in a transmission signal structure for each block including a plurality of frames for the audio signal. In the present embodiment, the frame structure of the IEC 60958 standard is used as this transmission signal structure.

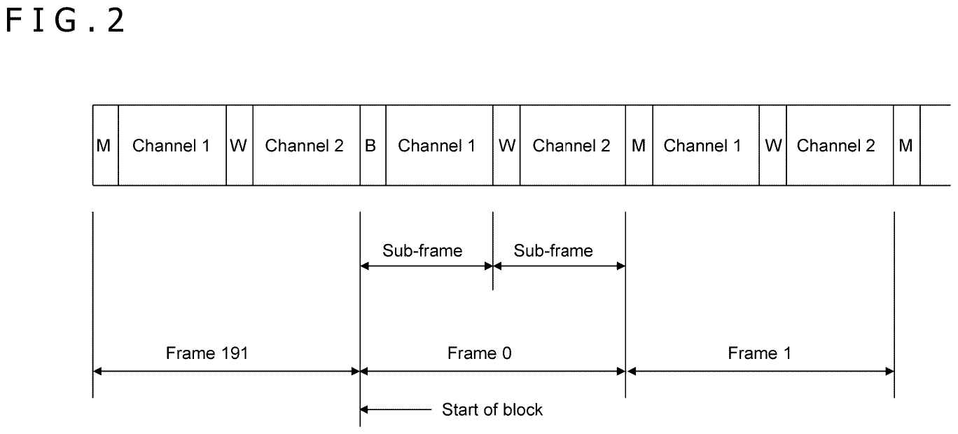

FIG. 2 illustrates the frame structure of the IEC 60958 standard. Each frame includes two sub-frames. In a case of two-channel stereo audio, a left channel signal is included in a first sub-frame, and a right channel signal is included in a second sub-frame.

A preamble is provided to a head of the sub-frame, “M” is added as the preamble to the left channel signal, and “W” is added as the preamble to the right channel signal. Note that “B” indicating a start of the block is added to a head preamble in every 192 frames. That is, one block includes 192 frames. The block is a unit included in the Channel status described later.

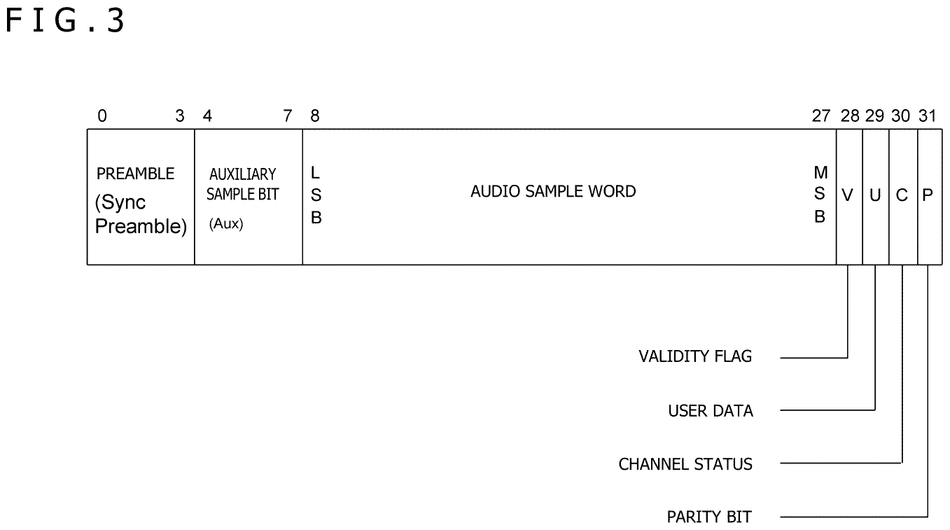

FIG. 3 illustrates a sub-frame structure of the IEC 60958 standard. The sub-frame includes a total of 32 time slots including 0th to 31st time slots. 0th to 3rd time slots indicate the preamble (Sync preamble). This preamble indicates any one of “M,” “W,” and “B” in order to indicate the discrimination between the left and right channels and the start position of the block, as described before.

4th to 27th time slots correspond to a main data field. When a code range equal to or smaller than 20 bits, for example, a code range in 20 bits or a code range in 16 bits is employed, a region of an Audio sample word from the 8th to 27th time slots is used. In this case, the audio signal is disposed without a space on an MSB (most significant bit) side and each of the remaining bits on an LSB (Least Significant Bit) side is padded by 0. Moreover, when a 24-bit code range is employed, in addition to the region of the Audio sample word from the 8th time slot to the 27th time slot, a region for Auxiliary sample bits from the 4th to 7th time slots is used. In this case, the audio signal is disposed in the 4th to 27th time slots.

A 28th time slot is a Validity flag for the main data field. A 29th time slot represents one bit of User data. A series of User data can be formed by accumulating these 29th time slots over frames. A message of this User data includes an IU (Information Unit) in 8 bits as a unit, and one message includes 3 to 129 Information Units.

“0” in 0 to 8 bits possibly exist between the Information Units. The head of the Information Unit is identified by a start bit of “1.” First 7 Information Units in the message are reserved and a user can set any information in the 8th and later Information Units. The messages are separated from each other by “0” in 8 or more bits.

A 30th time slot represents one bit of the Channel status. The Channel status can be formed by accumulating the 30th time slots over frames for each block. Note that the head position of the block is indicated by the preamble (the 0th to 3rd time slots) of “B” as described above.

The 31st time slot is a Parity bit. This Parity bit is added such that the numbers of “0”s and “1”s included in the 4th to 31st time slots are even numbers.

As described above, the object audio data includes the sound data (audio signal) and the position data relating to the sound source. The transmission processing section 202 converts the sound data (audio signal) relating to the sound source to data in floating-point format. In this sense, the transmission processing section 202 includes a conversion section. After that, the transmission processing section 202 disposes this data in the floating-point format in the region for the Audio sample word or the regions for the Audio sample word and the Auxiliary sample bits in the audio stream having the frame structure of the IEC 60958 standard.

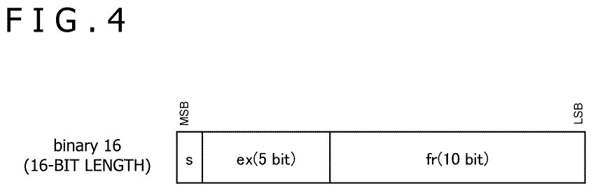

In the present embodiment, the data in the floating-point format is defined as data in 16-bit half-precision floating-point format (hereinafter appropriately referred to as “binary 16-bit data”). FIG. 4 illustrates a configuration of the binary 16-bit data. This binary 16-bit data has such a configuration that a sign part in 1 bit, an exponent part in 5 bits, and a fraction part in 10 bits are arranged from the MSB side.

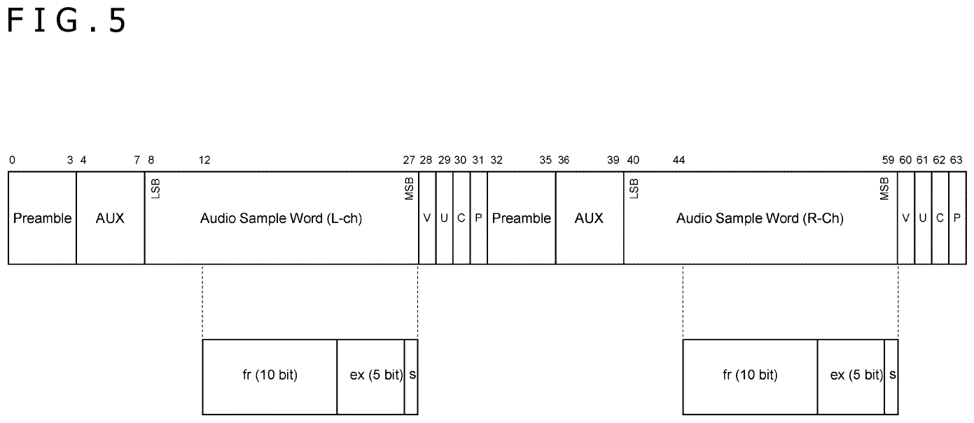

FIG. 5 is a diagram for illustrating a frame configuration in the audio stream having the frame structure of the IEC 60958 standard. The binary 16-bit data obtained by converting the sound data (audio signal) relating to the sound source is disposed in the region of the Audio sample word without a space on the MSB side, and 0 is filled in each remaining bit on the LSB side.

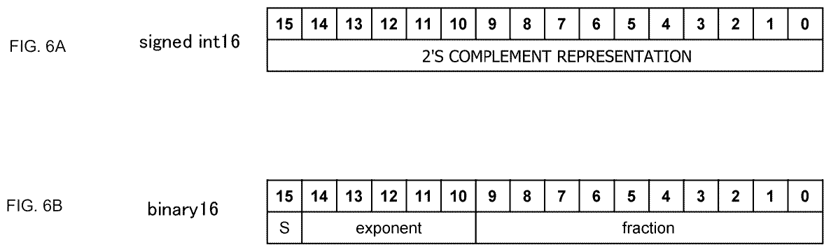

Here, FIG. 6 depict diagrams for describing the binary 16-bit data (binary16) in comparison with a signed integer 16-bit data (signed int16). FIG. 6(a) illustrates the signed integer 16-bit data, and FIG. 6(b) illustrates the binary 16-bit data. The signed integer 16 data is expressed as a two's complement, can express a range from −32768 to 32767, and has a 15-bit precision at the maximum.

In the binary 16-bit data, the exponent part in 5 bits indicates a range from −14 to 15, but a value from 1 to 30 obtained by adding 15 is actually stored. Note that 0 indicates a subnormal, that is, a state in which the fraction part cannot be normalized and the precision is insufficient, and 31 indicates the plus infinity or NaN (Not a Number). The binary 16-bit data has an expression range determined by this exponent part in 5 bits and can express a range from −65504 to 65504.

Moreover, in the binary 16-bit data, the fraction part has 10 bits, but such a configuration that the most significant bit is always 1 is used to omit the most significant bit to express the binary 16-bit data at the time of encoding. Thus, in the case of a normal, 1 is added to the MSB of the 10 bits of the fraction part to express a decimal value of “1.xxxxxxxxxx,” and significant bits are extended to 11 bits. Thus, the binary 16-bit data has a 11-bit precision in a case of a normal. Meanwhile, 10 bits of the fraction part expresses a decimal value of “0.xxxxxxxxxx” in a case of a sub-normal and the significant bits remain in 10 bits. Thus, the binary 16-bit data expresses a range approximately from −6.1*10\hat{ }−5 to 6.10\hat{ }5 in the case of a sub-normal and has a precision of 10 bits or less.

In the present embodiment, when the sound data (audio signal) relating to the sound source is converted into the binary 16-bit data, the maximum displacement of the sound data is set to a predetermined value smaller than the maximum value (=65504) in the range determined by the exponent part of the binary 16-bit data, for example, 1. As a result of this setting, even when an arithmetic operation in the format of the binary 16-bit data is continued on the reception side, the range of the value has a margin, and hence, an arithmetic operation of handling a signal exceeding the maximum displacement (100%) of the sound data (audio signal) relating to the sound source can be executed.

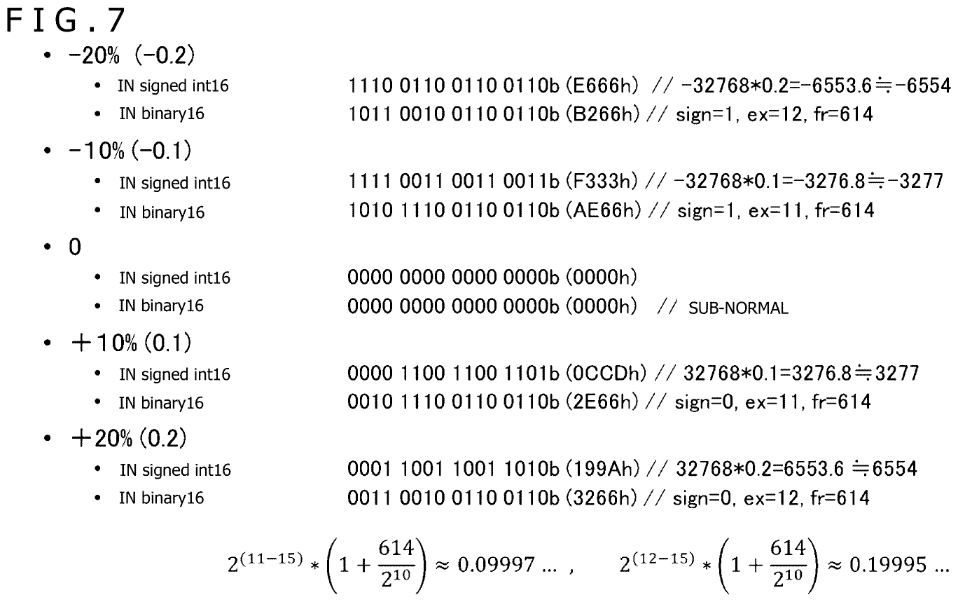

FIG. 7 illustrates a case in which the signed integer 16-bit data (signed int16) and the binary 16-bit data (binary16) are applied to the audio signal. There is illustrated a case in which the maximum displacement (100%) of the audio signal is set to “32768” in the signed integer 16-bit data while the maximum displacement (100%) of the audio signal is set to “1” in the binary 16-bit data.

In this case, −20% of the audio signal is represented as “1110 0110 0110 0110b (E666h)” in the signed integer 16-bit data and is represented as “1011 0010 0110 0110b (B266h)” in the binary 16-bit data. Note that, when this “1011 0010 0110 0110b (B266h)” is mistaken as signed integer 16-bit data, it represents −19866, that is approximately-61%.

Moreover, −10% of the audio signal is represented as “1111 0011 0011 0011b (F333h)” in the signed integer 16-bit data and is represented as “1010 1110 0110 0110b (AE66h)” in the binary 16-bit data. Note that, when this “1010 1110 0110 0110b (AE66h)” is mistaken as signed integer 16-bit data, it represents −20890, that is approximately −64%.

Moreover, +10% of the audio signal is represented as “0000 1100 1100 1101b (0CCDh)” in the signed integer 16-bit data and is represented as “0010 1110 0110 0110b (2E66h)” in the binary 16-bit data. Note that, when this “0010 1110 0110 0110b (2E66h)” is mistaken as signed integer 16-bit data, it represents 11878, that is approximately +36%.

Moreover, +20% of the audio signal is represented as “0001 1001 1001 1010b (199Ah)” in the signed integer 16-bit data and is represented as “0011 0010 0110 0110b (3266h)” in the binary 16-bit data. Note that, when this “0011 0010 0110 0110b (3266h)” is mistaken as signed integer 16-bit data, it represents 12902, that is approximately +39%.

Moreover, the transmission processing section 202 includes the position data relating to the sound source in the Channel status provided in the frame structure of the IEC 60958 standard, that is, the Channel status in the IEC 60958 standard.

For example, it is conceivable to assign two bytes to each of X, Y, and Z of three-dimensional coordinates included in the position data relating to the sound source. In this case, it is conceivable that (1) the signed integer 16-bit data is used and the decimeter (for example, 123.4 m for “1234”) or the centimeter (for example, 12 m 34 cm for “1234”) is employed as a unit. Moreover, in this case, it is conceivable that (2) the binary 16-bit data is used and the meter (for example, 1 m for “1.0” and 12.3 m for “12.3”) is employed as a unit.

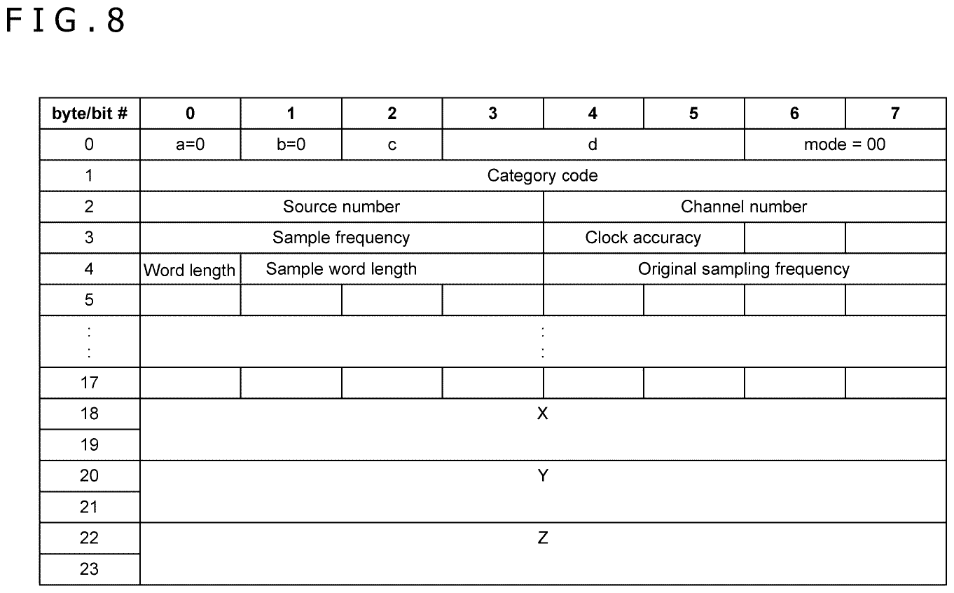

FIG. 8 is a table for schematically illustrating a format of the Channel status in the IEC 60958 standard. The Channel status is obtained by accumulating the 30th time slot in the subframe for each block (see FIG. 3). In this table, a content of the Channel status is arranged byte by byte in the vertical direction, and a bit configuration of each byte is indicated in the horizontal direction. A format for Consumer use is herein assumed, and only a principal potion is described.

“a” in a 0th bit of a 0th byte indicates the Channel status, is herein set such that a= “0,” and it is indicated that the Channel status is for the Consumer use. “b” in a 1st bit of the 0th byte indicates a data type, “0” indicates a linear PCM audio signal, and “1” indicates an audio signal other than the linear PCM.

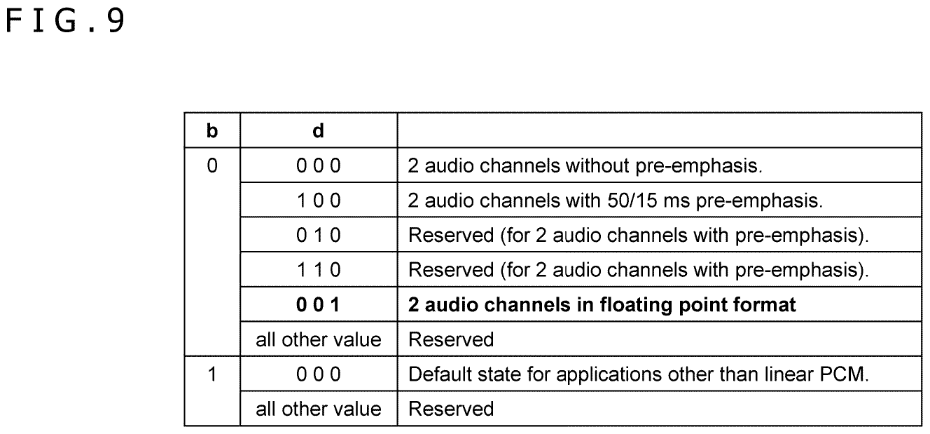

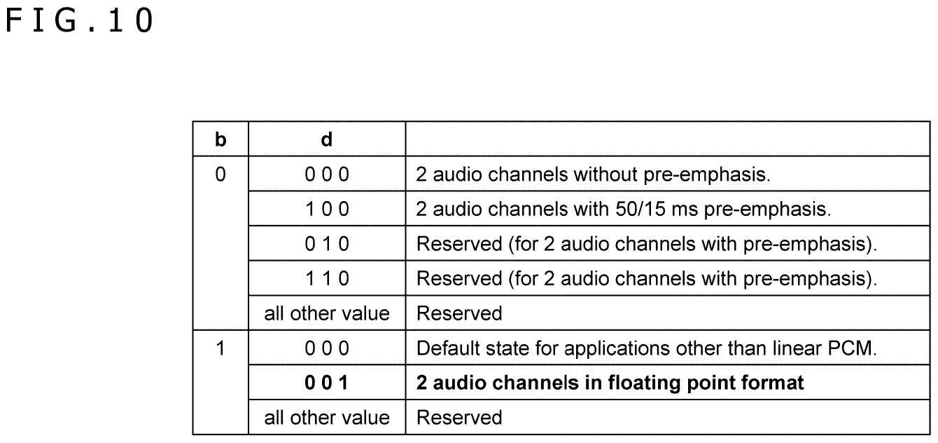

“d” in a 3rd bit to a 5th bit of the 0th byte indicates an additional format information. FIG. 9 is a table for illustrating an example of a definition of “b” in the 1st bit of the 0th byte and “d” in the 3rd bit to the 5th bit of the 0th byte. In this case, it is assumed that the data in floating-point format is a type of the linear PCM audio signal, b=“0” and d=“001” are newly defined, and the transmission of the data in the floating-point format is indicated. Moreover, FIG. 10 is a table for illustrating another example of the definition of “b” in the 1st bit of the 0th byte and “d” in the 3rd bit to the 5th bit of the 0th byte. In this case, it is assumed that the data in the floating-point format is not the linear PCM audio signal, b=“1” and d=“001” are newly defined, and the transmission of the data in the floating-point format is indicated.

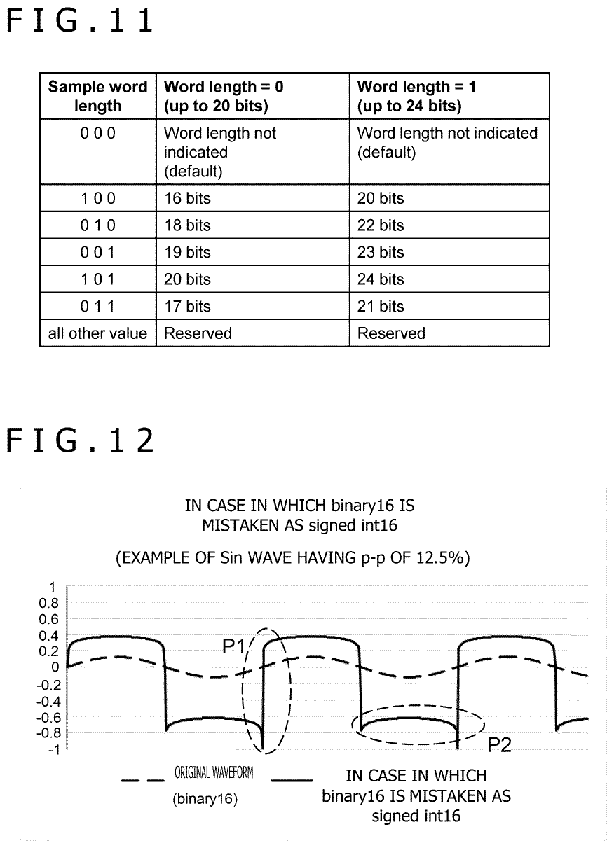

Moreover, with reference back to FIG. 8, “Word length” in a 0th bit of a 4th byte and “Sample word length” in a 1st bit to a 3rd bit of the 4th byte indicate a bit length of the audio signal to be transmitted. FIG. 11 illustrates examples of the definition of “Word length” and “Sample word length.”

For example, “Word length=0” and “Sample word length=100” indicate that the bit length of the audio signal is 16 bits. In the present embodiment, as the audio signal described before, the binary 16 data is transmitted, and “Word length=0” and “Sample word length=100” are defined to indicate that the bit length is 16 bits. Moreover, for example, “Word length=0” and “Sample word length=101” are defined to indicate that the bit length of the audio signal is 20 bits. Moreover, for example, “Word length=1” and “Sample word length=101” are defined to indicate that the bit length of the audio signal is 24 bits.

Moreover, with reference back to FIG. 8, 6 bytes in an 18th byte to a 23rd byte are newly provided regions for disposing the position data relating to the sound source. In the 18th byte to the 19th byte, X data in 2 bytes of the three-dimensional coordinates are disposed. In the 20th byte to the 21st byte, Y data in 2 bytes of the three-dimensional coordinates are disposed. In the 22nd byte to the 23rd byte, Z data in two bytes of the three-dimensional coordinates are disposed. Note that the region for disposing the position data relating to the sound source are not limited to the 18th byte to the 23rd byte.

As described before, in the transception system 10 illustrated in FIG. 1, the smart TV 200 generates the audio stream having the frame structure of the IEC 60958 standard including the object audio data, and transmits this audio stream to the AV amplifier 100 on the audio return channel or the enhanced audio return channel. The smart TV 200 converts, on this occasion, the sound data (audio signal) relating to the sound source included in the object audio data into the binary 16-bit data being the data in the floating-point format and transmits the converted sound data. Thus, it is possible to favorably execute the rendering processing (complicated arithmetic operation processing) of generating the audio signal for each speaker included in the speaker system 104 in the audio processing section 103 of the AV amplifier 100.

Moreover, as described before, in the transception system 10 illustrated in FIG. 1, the smart TV 200 includes, in the Channel status in the IEC 60958 standard, the information indicating that the data in the floating-point format is disposed in the region for the Audio sample word or the regions for the Audio sample word and the Auxiliary sample bits and further the information indicating the number of bits of this data in the floating-point format, when the audio stream having the frame structure of the IEC 60958 standard including the object audio data is generated. Thus, in the AV amplifier 100, it is possible to acquire these pieces of information from the Channel status and to appropriately execute the rendering processing in the audio processing section 103.

Moreover, in the transception system 10 illustrated in FIG. 1, the smart TV 200 disposes the data in the floating-point format obtained by converting the sound data (audio signal) relating to the sound source in the region for the Audio sample word or the regions for the Audio sample word and the Auxiliary sample bits and includes the position data relating to the sound source in the Channel status in the IEC 60958 standard when the audio stream having the frame structure of the IEC 60958 standard is generated. Thus, the sound data and the position data relating to the sound source and included in the object audio data can be transmitted in synchronism with each other from the smart TV 200 to the AV amplifier 100, and hence, a good 3D audio space can be reproduced in the AV amplifier 100.

### “Improvement Processing for Binary 16-Bit Data”

Note that there is described above that the sound data (audio signal) relating to the sound source included in the object audio data is converted into the binary 16-bit data being the data in the floating-point format and this binary 16-bit data is directly disposed in the region for the Audio sample word of the audio stream having the frame structure of the IEC 60958 standard.

In this case, for example, even when the AV amplifier 100 does not support the binary 16-bit data, or even when the AV amplifier 100 supports the binary 16-bit data, the Channel status is not correctly configured due to a loss in a channel bit or the like, and the state in which the binary 16-bit data has been transmitted cannot be recognized, there is such a possibility that the binary 16-bit data is mistaken as the signed integer 16-bit data and is processed so and a sharp waveform fluctuation at the time of zero cross and an unbalanced DC component are generated.

For example, FIG. 12 illustrates a waveform example in a case in which a data string expressing a sine wave having an amplitude of 12.5% (vibrates in a range of −0.125 to +0.125) in the binary 16-bit data (binary16) is mistaken as the signed integer 16-bit data (signed int16). A broken line indicates a waveform expressing the sine wave having the amplitude of 12.5% (y=0.125*sin x) in the binary 16-bit data. The solid line indicates a waveform in the case in which the binary 16-bit data is mistaken as the signed integer 16-bit data. Note that a full scale of the signed integer 16-bit data is −32768 to +32767.

When the binary 16-bit data is mistaken as the signed integer 16-bit data as described above, a sharp waveform fluctuation at the time of zero cross occurs as indicated by a broken-line ellipsoidal frame P1, and an unbalanced DC component occurs as indicated by a broken-line ellipsoidal frame P2.

It is considered that these phenomena are caused by the number in the exponent part being the offset value obtained by adding 15 to the original value in the binary 16-bit data. The exponent is also a value equal to or less than 0 in a vicinity of zero, but becomes a value equal to or less than 15 as a result of the addition of 15. In this case, the exponent part has the 5-bit length, and hence, the MSB is 0. For example, 15 is 01111b. The signed integer 16-bit data is expressed as a two's complement, and when 0 exists at a position close to the MSB and the signed integer 16-bit data represents a negative value, this signed integer 16-bit data has a large negative value. For example, as the binary 16-bit data, 0.0625 being a half of 0.125 is expressed as 0x2C00 and −0.0625 is expressed as 0xAC00. When they are mistaken as integer 16-bit data, they are 11264 and −21504, respectively.

There are herein proposed an improvement plan 1 and an improvement plan 2 of applying predetermined processing to the binary 16-bit data obtained by converting the sound data (audio signal) relating to the sound source and included in the object audio data and disposing the processed binary 16-bit data in the region of the Audio sample word of the audio stream having the frame structure of the IEC 60958 standard, in order to suppress the sharp waveform fluctuation at the time of zero cross and the unbalanced DC component in the case in which the binary 16-bit data is mistaken as the signed integer 16-bit data.

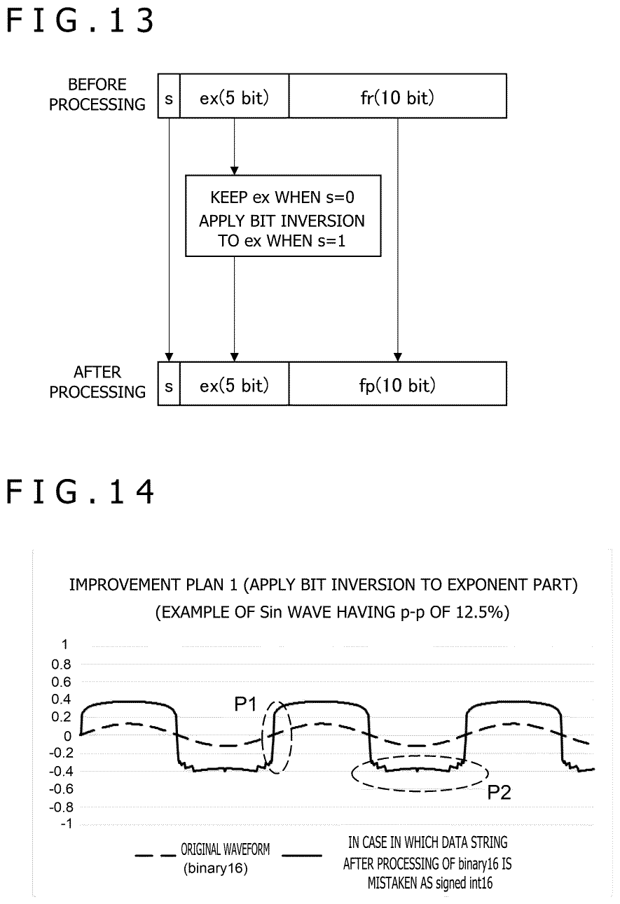

First, the improvement plan 1 is described. This improvement plan 1, as illustrated in FIG. 13, applies, in a case in which the sign part(s) indicates the negative sign for unprocessed data, the bit inversion processing is applied to the exponent part in 5 bits of the data, thereby obtaining the data that has been processed.

FIG. 14 is a diagram for illustrating a waveform example in a case in which, in a case in which the data string expressing the sine wave having the amplitude of 12.5% (vibrates in the range of −0.125 to +0.125) in the binary 16-bit data (binary16) is processed through the improvement plan 1, this data string is mistaken as the signed integer 16-bit data (signed int16). A broken line indicates the waveform expressing the sine wave having the amplitude of 12.5% (y=0.125*sin x) in the binary 16-bit data. A solid line indicates a waveform in a case in which the data string after the binary 16-bit data is processed through the improvement plan 1 is mistaken as the signed integer 16-bit data.

In the case in which the data string of the binary 16-bit data is processed through the improvement plan 1 as described above, even in a case in which this data string is mistaken as the signed integer 16-bit data, the sharp waveform fluctuation at the time of the zero cross is suppressed as indicated by the broken-line ellipsoidal frame P1, and the unbalanced DC component is suppressed as indicated by the broken-line ellipsoidal frame P2, compared with the case illustrated in FIG. 12. In the case of this improvement plan 1, in a case in which the sign part(s) is checked and is determined as negative, the entire exponent part in 5 bits is simply inverted, hence, implementation thereof is simple, and even hardware implementation can easily be achieved.

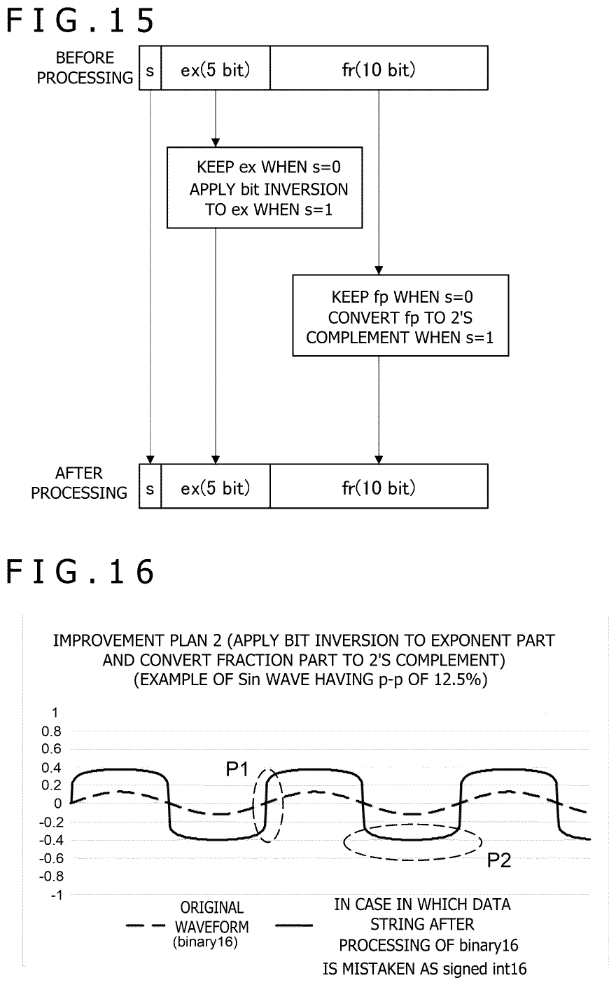

The improvement plan 2 is now described. This improvement plan 2, as illustrated in FIG. 15, applies, in a case in which the sign part(s) indicates the negative sign, the bit inversion processing to the exponent part in 5 bits of the unprocessed data and applies conversion processing to a two's complement to the fraction part in 10 bits, thereby obtaining the data that has been processed.

FIG. 16 is a diagram for illustrating a waveform example in a case in which, in a case in which the data string expressing the sine wave having the amplitude of 12.5% (vibrates in the range of −0.125 to +0.125) in the binary 16-bit data (binary16) is processed through the improvement plan 2, this data string is mistaken as the signed integer 16-bit data (signed int16). A broken line indicates the waveform expressing the sine wave having the amplitude of 12.5% (y=0.125*sin x) in the binary 16-bit data. A solid line indicates a waveform in the case in which the data string obtained after the binary 16-bit data is processed through the improvement plan 2 is mistaken as the signed integer 16-bit data.

In a case in which the data string of the binary 16-bit data is processed through the improvement plan 2 as described above, even in a case in which this data string is mistaken as the signed integer 16-bit data, the sharp waveform fluctuation at the time of the zero cross is suppressed as indicated by the broken-line ellipsoidal frame P1, and the unbalanced DC component is suppressed as indicated by the broken-line ellipsoidal frame P2, compared with the case illustrated in FIG. 12. In the case of this improvement plan 2, the complicated processing is required compared with the improvement plan 1 described above, and a waveform at the time of the negative value is clean compared with the improvement plan 1.

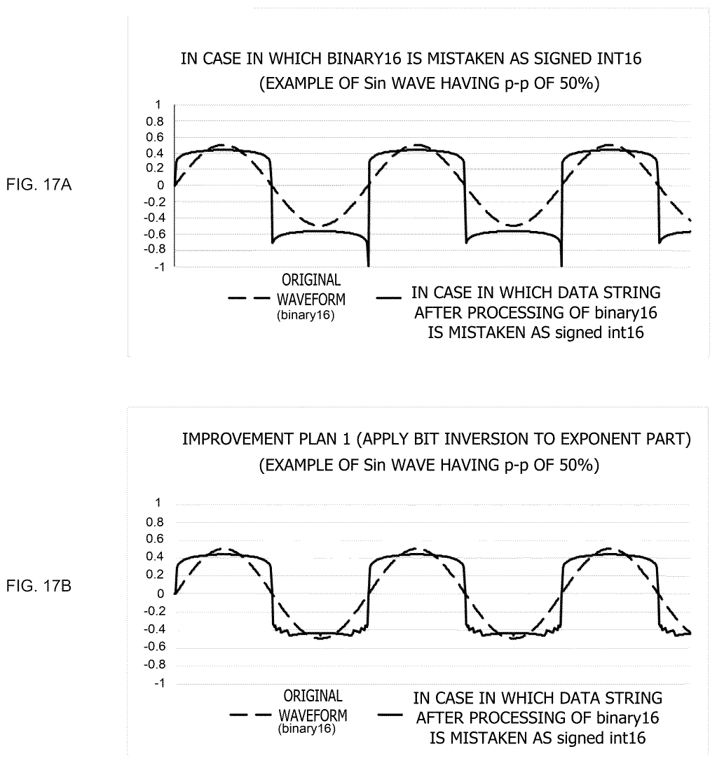

In the description given above, the sine wave having the amplitude of 12.5% (vibrates in the range of −0.125 to +0.125) is exemplified, the same applies to a case in which the amplitude is larger than that in this example. FIG. 17(a) is a diagram for illustrating a waveform example in a case in which a data string expressing a sine wave having an amplitude of 50% (vibrates in a range of −0.5 to +0.5) in the binary 16-bit data (binary16) is mistaken as the signed integer 16-bit data (signed int16). A broken line indicates the waveform obtained by expressing the sine wave having the amplitude of 50% (y=0.5*sin x) in the binary 16-bit data. The solid line indicates a waveform in the case in which the binary 16-bit data is mistaken as the signed integer 16-bit data. Note that the full scale of the signed integer 16-bit data is −32768 to +32767.

FIG. 17(b) is a diagram for illustrating a waveform example in a case in which, in a case in which the data string expressing the sine wave having the amplitude of 50% (vibrates in the range of −0.5 to +0.5) in the binary 16-bit data (binary16) is processed through the improvement plan 1, this data string is mistaken as the signed integer 16-bit data (signed int16). A broken line indicates the waveform obtained by expressing the sine wave having the amplitude of 50% (y=0.5*sin x) in the binary 16-bit data. A solid line indicates a waveform in the case in which the data string obtained after the binary 16-bit data is processed through the improvement plan 1 is mistaken as the signed integer 16-bit data.

Also in such a case in which the amplitude is increased, the binary 16-bit data possibly generates the sharp waveform fluctuation at the time of zero cross and the unbalanced DC component in a case in which the binary 16-bit data is simply used and the data string thereof is processed while the data string is mistaken as the signed integer 16-bit data. Moreover, in this case, the sharp waveform fluctuation at the time of zero cross is suppressed, and moreover, the unbalanced DC component is suppressed, as indicated by the broken-line ellipsoidal frame P2, by processing the binary 16-bit data through the improvement plan 1. Illustration of a waveform for the improvement plan 2 is omitted, but a processing effect similar to that of the improvement plan 1 is certainly provided.

### (Precision Improvement for Data in Floating-Point Format]

In the description given above, there is described the example in which the sound data (audio signal) relating to the sound source is converted into the binary 16-bit data (data in half-precision floating-point format in 16 bits) as the object audio data. The binary 16-bit data has the 11-bit precision in the range of the normal as described above, but it is conceivable to use data in floating-point format having an increased number of bits in the fraction part to further increase the precision.

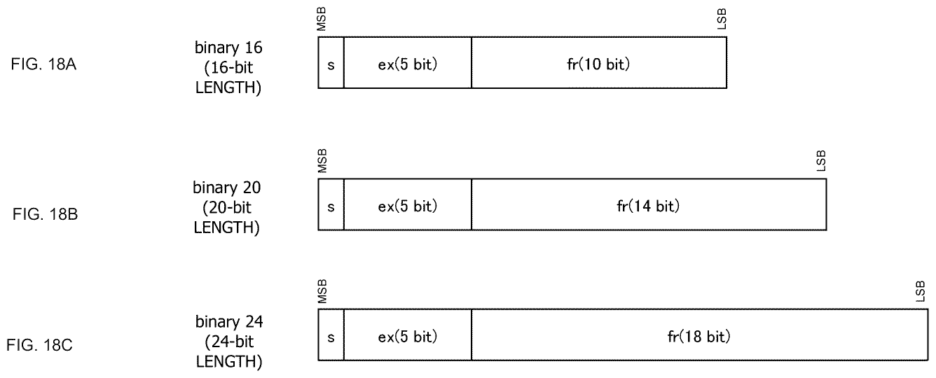

Each of FIG. 18(b) and FIG. 18(c) illustrates an example of the data in the floating-point formation capable of increasing the precision compared with that of the binary 16-bit data. Note that FIG. 18(a) illustrates the binary 16-bit data (binary16) similar to that illustrated in FIG. 4.

The data in the floating-point format (hereinafter appropriately referred to as “binary 20-bit data (binary20)”) of FIG. 18(b) has a 20-bit length and has such a configuration that a sign part in one bit, an exponent part in 5 bits, and a fraction part in 14 bits are arranged from the MSB side. Also in the case of this binary 20-bit data, the exponent part has 5 bits similarly to the binary 16-bit data. In the case of this binary 20-bit data, the number of bits of the fraction part is 14 and hence has a 15-bit precision in the range of the normal (corresponding to a 16-bit signed integer).

Moreover, the data in the floating-point format (hereinafter appropriately referred to as “binary 24-bit data (binary24)”) of FIG. 18(c) has a 24-bit length and has such a configuration that a sign part in one bit, an exponent part in 5 bits, and a fraction part in 18 bits are arranged from the MSB side. Also in the case of this binary 20-bit data, the exponent part has 5 bits similarly to the binary 16-bit data. In the case of this binary 24-bit data, the number of bits of the fraction part is 18 and hence has a 19-bit precision in the range of the normal (corresponding to a 20-bit signed integer).

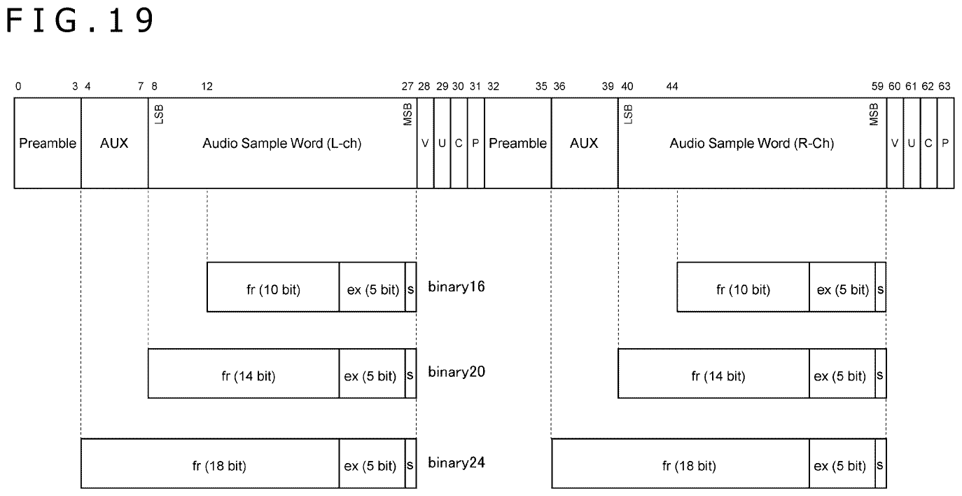

FIG. 19 is a diagram for illustrating a disposition example of the frame structure of the IEC 60958 standard in the audio stream in a case in which the binary 20-bit data or the binary 24-bit data is used. The binary 20-bit data is disposed in the region for the Audio sample word. Moreover, the binary 24-bit data is disposed in the region for the Audio sample word and the region for the Auxiliary sample bits.

In this case, a portion of the region of the Audio sample word up to the exponent part as viewed from the MSB side has the identical structure to that in the case in which the binary 16-bit data is disposed. Moreover, the fraction part is normalized, and hence, even when 4 bits or 8 bits on a lower bit side of the fraction part of the binary 20-bit data or the binary 24-bit data is cut into 16-bit data, a value rounded as a binary 16-bit data (a value close to the original value) is obtained. That is, even when the reception side treats, by mistake, the disposed binary 20-bit data or binary 24-bit data as the binary 16-bit data, only a decrease in precision occurs, and a failure can be avoided.

Moreover, in the description given above, there is described the example in which the one piece (1 channel) of object audio data is transmitted from the smart TV 200 to the AV amplifier 100, it is possible to transmit 2 pieces (2 channels) or more of object audio data and, further, to transmit the object audio data together with a usual audio signal. In this case, each piece of data is only required to be divided into and disposed in the frames in the audio stream having the frame structure of the IEC 60958 standard.

Moreover, in the description given above, there is described the example in which the HDMI sink is the smart TV, but the HDMI sink is not limited to this and may be, for example, a TV without an Internet connection function, a set top box, or a PC.

### Second Embodiment

### (Configuration Example of Transception System)

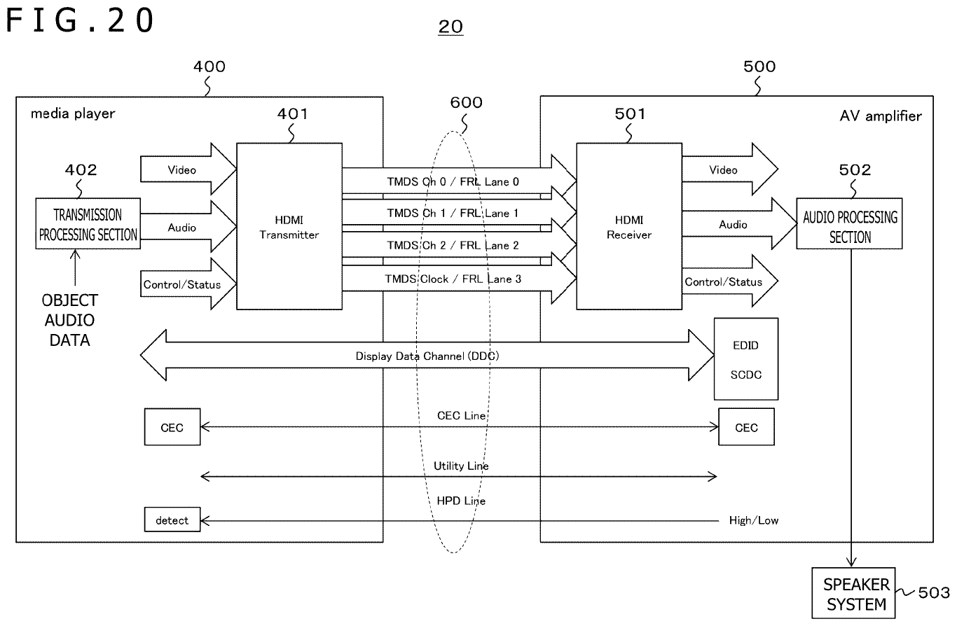

FIG. 20 illustrates a configuration example of a transception system 20 as a second embodiment. This transception system 20 is configured such that a media player 400 as the HDMI source and an AV amplifier 500 as the HDMI sink are connected via an HDMI cable 600.

The media player 400 transmits, to the AV amplifier 500 on a plurality of channels, differential signals corresponding to a non-compressed pixel data relating to an image for one screen in the effective image period (hereinafter also appropriately referred to as an active video period) being the period obtained by removing the horizontal blanking period and the vertical blanking period from the period from one vertical synchronous signal to a next vertical synchronous signal and transmits, to the AV amplifier 500 on the plurality of channels, differential signals corresponding to at least an audio data and a control data accompanying the image, other types of auxiliary data, and the like in the horizontal blanking period or the vertical blanking period.

That is, the media player 400 includes an HDMI transmitter 401. The HDMI transmitter 401, for example, converts the pixel data relating to the non-compressed image into the corresponding differential signals and serially transmits the differential signals on the three TMDS channels #0, #1, and #2 being the plurality of channels to the AV amplifier 500 connected via the HDMI cable 600.

Moreover, the HDMI transmitter 401 converts audio data accompanying the non-compressed image and, further, required control data, other types of auxiliary data, and the like into the corresponding differential signals and serially transmits the differential signals on the three TMDS channels #0, #1, and #2 being the plurality of channels to the AV amplifier 500 connected via the HDMI cable 600.

Further, the HDMI transmitter 401 transmits a pixel clock synchronized with the pixel data, which is transmitted on the three TMDS channels #0, #1, and #2, on the TMDS clock channel to the AV amplifier 500 connected via the HDMI cable 600. On one TMDS channel #i (i=0, 1, 2), the pixel data in 10 bits is transmitted during one clock of the pixel clock.

In this configuration, the TMDS coding is the 8-bit/10-bit conversion coding of converting data in 8 bits into data in 10 bits and is coding which reduces the transition points from previous data, thereby suppressing the adverse effect such as the unnecessary radiation and then maintains the DC balance. Thus, the run length of the coding cannot theoretically be guaranteed and hence the DC coupling, and the independent transmission of the clock are indispensable.

The AV amplifier 500 receives the differential signals corresponding to the pixel data transmitted from the media player 400 on the plurality of channels in the active video period and receives the differential signals corresponding to the audio data and the control data transmitted from the media player 400 on the plurality of channels in the horizontal blanking period or the vertical blanking period.

That is, the AV amplifier 500 includes an HDMI receiver 501. The HDMI receiver 501 receives the differential signals corresponding to the pixel data and the differential signals corresponding to the audio data and the control data transmitted on the TMDS channels #0, #1, and #2 from the media player 300 connected via the HDMI cable 600 in synchronism with the pixel clock similarly transmitted on the TMDS clock channel from the media player 400.

Note that there is described above the example in which the image data, the audio data, and the control data are transmitted on the TMDS channels #0, #1, and #2 and the pixel clock is transmitted on the TMDS clock channel and this example corresponds to HDMI 1.4 or earlier and HDMI 2.0. In the case of HDMI 2.1, transmission through use of the FRL lanes #0, #1, #2, and #3 is executed. In this case, the TMDS clock channel corresponds to the FRL lane #3.

In this case, the data transmission on the fixed rate link (FRL) packets through use of the three lanes #0 to #2 or the four lanes #0 to #3 is executed. In this configuration, the FRL Character coding is the 16-bit/18-bit conversion coding of converting data in 16 bits into data in 18 bits, is a coding which maintains the DC balance and is a coding which allows the clock extraction.

In this transception system 20, the media player 400 extracts, from, for example, an HDD, together with image data, the object audio data associated with this image and transmits the image data and the object audio data to the AV amplifier 400.

That is, the AV amplifier 400 includes a transmission processing section 402. This transmission processing section 402 inputs the object audio data and generates an audio stream including this object audio data. A detailed description is omitted, but the transmission processing section 402 is configured similarly to the transmission processing section 202 of the smart TV 200 of the transception system 10 illustrated in FIG. 1, inputs the object audio data, and generates the audio stream including this object audio data, that is, the audio stream having the frame structure of the IEC 60958 standard.

In this case, the transmission processing section 402 converts the sound data (audio signal) relating to the sound source included in the object audio data into the data in the floating-point format and disposes this data in the floating-point format in the region for the Audio sample word or the regions for the Audio sample word and the Auxiliary sample bits in the audio stream having the frame structure of the IEC 60958 standard (see FIG. 5 and FIG. 19). Moreover, the transmission processing section 402 includes the position data relating to the sound source included in the object audio data in the Channel status provided in the frame structure of the IEC 60958 standard, that is, the Channel status in the IEC 60958 standard (see FIG. 8).

The audio stream generated in the transmission processing section 402 is supplied as the audio data to the HDMI transmitter 401. The HDMI transmitter 401 packetizes this audio stream, inserts the packetized audio stream in the data island period of the TMDS transmission data, and transmits the packetized audio stream to the AV amplifier 500.

In this transception system 20, the AV amplifier 500 outputs, as the audio data, from the HDMI receiver 501, the audio stream having the frame structure of the IEC 60958 standard and transmitted from the media player 400. The AV amplifier 500 executes the rendering processing through use of the object audio data included in this audio stream, thereby generating the audio signal for each speaker included in the speaker system.

That is, the AV amplifier 500 includes an audio processing section 502. The audio processing section 503 extracts the object audio data from the audio stream output from the HDMI receiver 501, executes the rendering processing through use of this object audio data, thereby generating the audio signal for each speaker included in the speaker system 503, and supplies the audio signal to the corresponding speaker in the speaker system 503.

As described before, in the transception system 20 illustrated in FIG. 20, the media player 400 generates the audio stream having the frame structure of the IEC 60958 standard including the object audio data, packetizes the audio stream, inserts the packetized audio stream into the data island period of the TMDS transmission data, and transmits the audio stream to the AV amplifier 500, and converts, on this occasion, the sound data (audio signal) relating to the sound source and included in the object audio data into the data in the floating-point format and transmits the converted sound data. Thus, as in the audio processing section 103 of the AV amplifier 100 of the transception system 10 illustrated in FIG. 1, the rendering processing (complicated arithmetic operation processing) of generating the audio signal for each speaker included in the speaker system 503 in the audio processing section 502 of the AV amplifier 500 can favorably be executed.

Note that, there is described above the configuration that the position data relating to the sound source and included in the object audio data is included in the Channel status provided in the frame structure of the IEC 60958 standard, that is, the Channel status in the IEC 60958 standard and is then transmitted. However, for example, it is conceivable to define a new InfoFrame packet including the position data relating to the sound source, to insert this InfoFrame packet into the data island period of the TMDS transmission data, and to transmit the inserted InfoFrame packet to the AV amplifier 500.

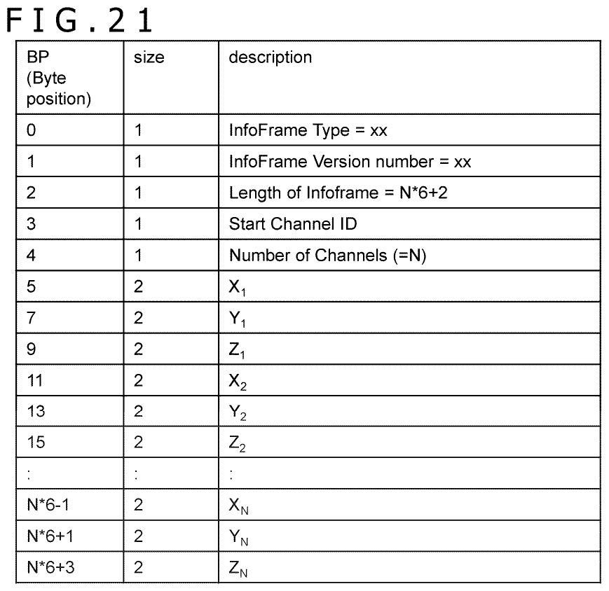

FIG. 21 is a table for illustrating a packet configuration example of the new InfoFrame including position data relating to the sound source. “InfoFrame Type” indicating a type of the InforFrame packet is defined in a 0th byte. Version information “InfoFrame Version number” relating to packet data definition is described in a 1st byte. Information “Length of InforFrame” indicating a packet length is described in a 2nd byte. In this configuration example, it is assumed that N channels, that is, N pieces of object audio data are simultaneously transmitted and hence “Length of InforFrame=N*6+2.”

Information “Start Channel ID” indicating a start channel is described in a 3rd byte. Moreover, information “Number of Channels” indicating the number of channels is described in a 4th byte. Further, in the following bytes, there are sequentially disposed pieces of data each in 2 bytes for each of X, Y, Z of the three-dimensional coordinates being the position data relating to the sound source for the N channels.

Note that, in the case of the HDMI, the InfoFrame is restricted to 30 bytes or less, and hence, N is restricted to 4 or less. Thus, when the position data relating to the sound sources and included in 5 channels (5 pieces) or more of the object audio data is to be transmitted, a plurality of InfoFrames is used for the transmission. For example, when the position data relating to the sound sources and included in 7 channels (7 pieces) of the object audio data is to be transmitted, 2 InfoFrames are used. In this case, the 1st InfoFrame in which the position data relating to the sound sources and included in the object audio data for 1st to 4th channels is described, there are provided such settings as “Start Channel ID=1” and “Number of Channels=4” and, in the 2nd InfoFrame in which the position data relating to the sound sources and included in the object audio data for 5th to 7th channels is described, there are provided such settings as “Start Channel ID=5” and “Number of Channels=3.”

### Third Embodiment

### (Configuration Example of Transception System)

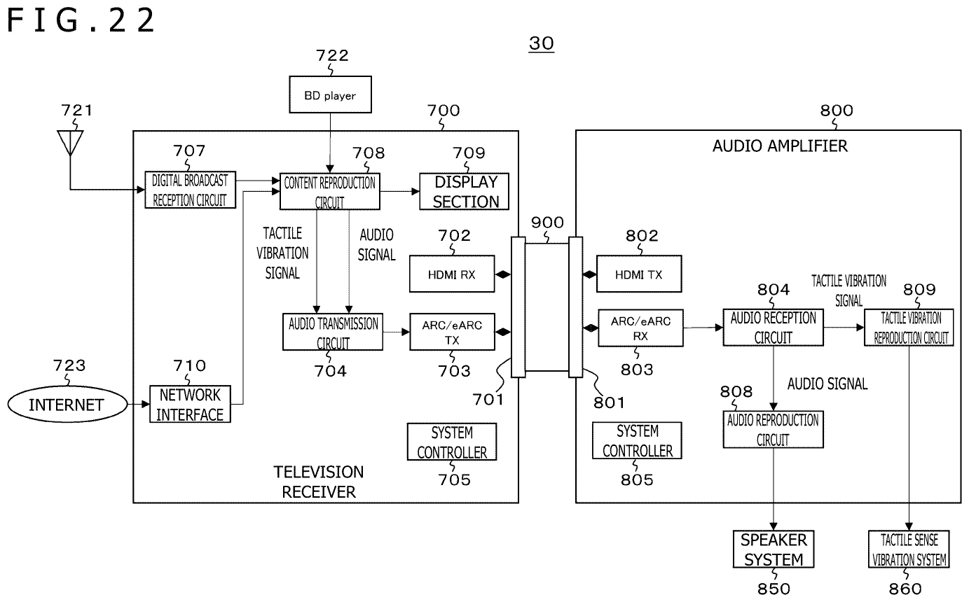

FIG. 22 illustrates a configuration example of a transception system 30 as a third embodiment. This transception system 30 is configured such that a television receiver 700 as the HDMI source and an audio amplifier 700 as the HDMI sink are connected via an HDMI cable 900.

To the television receiver 700, an HDMI terminal 701 to which an HDMI reception section (HDMI RX) 702 and an ARC/eARC transmission section (ARC/eARC Tx) 703 are connected is provided. To the audio amplifier 800, an HDMI transmission section (HDMI TX) 802 and an ARC/eARC reception section (ARC/eARC Rx) 803 are provided. One end of the HDMI cable 900 is connected to the HDMI terminal 701 of the television receiver 700, and the other end thereof is connected to the HDMI terminal 801 of the audio amplifier 800.

The television receiver 700 includes the HDMI reception section 702, the ARC/eARC transmission section 703, and an audio transmission circuit 704. Moreover, the television receiver 700 includes a system controller 705, a digital broadcast reception circuit 707, a content reproduction circuit 708, a display section 709, and a network interface 710. Moreover, in the illustrated example, for the sake of simplified description, each section of an image system is appropriately omitted.

The system controller 705 controls an operation of each section of the television receiver 700. The digital broadcast reception circuit 707 processes a television broadcast signal input from a reception antenna 721 and outputs signals (a video signal, multi-channel audio signals (linear PCM signals), and tactile vibration signals on a predetermined number of channels) relating to broadcast content in a first mode or signals (tactile vibration signals on a predetermined number of channels) in a second mode.

In this configuration, the multi-channel audio signals include audio signals on a plurality of channels. Moreover, the tactile vibration signals on the predetermined number of channels relating to the signals in the first mode serve to acquire vibration in synchronism with the video and the audio. Moreover, the tactile vibration signals on the predetermined number of channels relating to the signals in the second mode serve to acquire vibration which does not directly relate to the video or the audio and is used for massage, healing, and the like.

The network interface 710 communicates with an external server via the Internet 723 and outputs signals (a video signal, multi-channel audio signals (linear PCM signals), and tactile vibration signals on a predetermined number of channels) relating to net content in the first mode or signals (tactile vibration signals on a predetermined number of channels) in the second mode.

Moreover, a BD player 722 outputs, through a reproduction operation, signals (a video signal, multi-channel audio signals (linear PCM signals), and tactile vibration signals on a predetermined number of channels) in the first mode relating to reproduction content or signals (tactile vibration signals on a predetermined number of channels) in the second mode.

The content reproduction circuit 708 selectively extracts the signals in the first mode or the signals in the second mode acquired in the digital broadcast reception circuit 707, the network interface 710, or the BD player 722.

After that, the content reproduction circuit 708 transmits, when the signals in the first mode are extracted, the video signal to the display section 709. The display section 709 displays an image based on this video signal.

Moreover, the content reproduction circuit 708 transmits, when the signals in the first mode are extracted, the multi-channel audio signals and the tactile vibration signals on the predetermined number of channels to the audio transmission circuit 704. The audio transmission circuit 704 simultaneously transmits, to the audio amplifier 800, the multi-channel audio signals (linear PCM signals) and the tactile vibration signals on the predetermined number of channels.

Moreover, the content reproduction circuit 708 transmits, when the signals in the second mode are extracted, the tactile vibration signals on the predetermined number of channels to the audio transmission circuit 704. The audio transmission circuit 704 transmits the tactile vibration signals on the predetermined number of channels to the audio amplifier 800.

The audio transmission circuit 704 generates, when the signals in the first mode are extracted in the content reproduction circuit 708 and hence the multi-channel audio signals and the tactile vibration signals on the predetermined number of channels are transmitted, an audio stream including the multi-channel audio signals and the tactile vibration signals on the predetermined number of channels. Moreover, the audio transmission circuit 704 generates, when the signals in the second mode are extracted in the content reproduction circuit 708 and hence the tactile vibration signals on the predetermined number of channels are transmitted, an audio stream including the tactile vibration signals on the predetermined number of channels.

A detailed description is omitted, but the audio transmission circuit 704 is configured similarly to the transmission processing section 202 of the smart TV 200 of the transception system 10 illustrated in FIG. 1, generates the audio stream including the multi-channel audio signals and the tactile vibration signals on the predetermined number of channels or the tactile vibration signals on the predetermined number of channels, that is, the audio stream having the frame structure of the IEC 60958 standard.

In this case, the audio transmission circuit 704 converts the tactile vibration signal into the data in the floating-point format and disposes this data in the floating-point format in the region for the Audio sample word or the regions for the Audio sample word and the Auxiliary sample bits in the audio stream having the frame structure of the IEC 60958 standard (see FIG. 5 and FIG. 19). Moreover, in this case, when the audio signals and the tactile vibration signals on the plurality of channels are included in the audio stream having the frame structure of the IEC 60958 standard, the audio transmission circuit divides the data relating to each channel into frames and disposes the frames.

The ARC/eARC transmission section 703 transmits the audio stream generated in the audio transmission circuit 704 to the audio amplifier 800 on the audio return channel or the enhanced audio return channel which uses the Utility Line and the HPD Line of the HDMI cable 900.

In this case, in the audio stream, there are included the multi-channel audio signals and the tactile vibration signals on the predetermined number of channels relating to the signals in the first mode or the tactile vibration signals on the predetermined number of channels relating to the signals in the second mode. Configuration information relating to the signals included in the audio stream is included in, for example, the Channel status configured for each block, that is, the Channel status in the IEC 60958 standard, a detailed description of which is omitted.

The audio amplifier 800 includes the HDMI transmission section 802, the ARC/eARC reception section 803, and an audio reception circuit 804. Moreover, the audio amplifier 800 includes a system controller 805, an audio reproduction circuit 808, and a tactile vibration reproduction circuit 809. The system controller 805 controls an operation of each section of the audio amplifier 800.

The ARC/eARC reception section 803 receives, from the television receiver 700, the audio stream having the frame structure of the IEC 60958 standard on the audio return channel or the enhanced audio return channel. In this audio stream, as described before, there are included the multi-channel audio signals and the tactile vibration signals on the predetermined number of channels relating to the signals in the first mode or the tactile vibration signals on the predetermined number of channels relating to the signals in the second mode.

The audio reception circuit 804 acquires the multi-channel audio signals and the tactile vibration signals on the predetermined number of channels relating to the signals in the first mode or the tactile vibration signals on the predetermined number of channels relating to the signals in the second mode included in the audio stream received by the ARC/eARC reception section 803. In this case, the multi-channel audio signals and the tactile vibration signals on the predetermined number of channels relating to the signals in the first mode or the tactile vibration signals on the predetermined number of channels relating to the signals in the second mode are extracted on the basis of the configuration information included in the transmission signal.

The audio reproduction circuit 808 amplifies the multi-channel audio signals relating to the signals in the first mode acquired by the audio reception circuit 804 for each channel and transmits the multi-channel audio signals to the speaker system 850 including speakers each corresponding to each channel. As a result, audio reproduction is executed through use of the multi-channel audio signals in the speaker system 850.

Moreover, the tactile vibration reproduction circuit 809 amplifies the tactile vibration signals on the predetermined number of channels relating to the signals in the first mode or the tactile vibration signals on the predetermined number of channels relating to the signals in the second mode acquired in the audio reception circuit 804 for each channel and transmits the tactile vibration signals to the tactile vibration system 860 having the vibration devices each corresponding to each channel. As a result, in the tactile vibration system 860, vibration reproduction is executed on the basis of the tactile vibration signals on the predetermined number of channels. Note that, in this case, in the tactile vibration reproduction circuit 809, there is applied arithmetic operation processing of adjusting a gain according to sensitivity of each user, sensitivity of a portion to be stimulated, sensitivity of the vibration device, and further nonlinearity of the vibration device.

In this case, as described above, in a case in which the signals in the first mode are handled, the tactile vibration signals on the predetermined number of channels are transmitted simultaneously with the multi-channel audio signals, and hence, this vibration reproduction is correctly synchronized with the audio reproduction and is also synchronized with the video display in the display section 709 of the television receiver 700. Moreover, in a case in which the signals in the second mode are handled, only the tactile vibration signals on the predetermined number of channels are transmitted, hence, the audio reproduction is not executed, and only the vibration reproduction for the massage and healing, for example, is executed.

As described above, in the transception system 30 illustrated in FIG. 22, the television receiver 700 generates the audio stream having the frame structure of the IEC 60958 standard including the tactile vibration signals, transmits this audio stream to the audio amplifier 800 on the audio return channel or the enhanced audio return channel, and converts, on this occasion, the tactile vibration signals into the data in the floating-point format, thereby transmitting the data in the floating-point format. Thus, in the tactile vibration reproduction circuit 809 of the audio amplifier 800, it is possible to favorably execute the arithmetic operation processing (complicated arithmetic operation processing) of adjusting the gain according to the sensitivity of each user, the sensitivity of the portion to be stimulated, the sensitivity of the vibration device, and further the nonlinearity of the vibration device.

### 4. Modification Examples

Note that, in the embodiment described above, there is described the examples in which the HDMI ARC/eARC or the HDMI transmission path is used as the transmission path for the audio stream having the IEC 60958 structure, but it is conceivable to use, as the IEC 60958 transmission path, the IEC 61883-7 transmission path, the MHL transmission path, the display port transmission path (DP transmission path), and, further, a coaxial cable or an optical cable.

Moreover, the preferred embodiments of the present disclosure are described in details with reference to the accompanying drawings, but the technical scope of the present disclosure is not limited to these examples. It is obvious that various modification examples and correction examples may be conceived of within the scope of the technical ideas described in the scope of claims by those having ordinary knowledge in the technical field of the present disclosure. Needless to say, it is understood that these examples also belong to the technical scope of the present disclosure.

Moreover, the effects described in the present description are merely explanatory and illustrative and are not limitative. That is, the technology according to the present disclosure can achieve other effects apparent to those skilled in the art from the description in the present description, in addition to or in place of the effects described above.

Also, the technology can also take the following configurations.

(1)

A transmission apparatus including:
a conversion section that converts a vibration signal to data in floating-point format; and
a transmission section that transmits the data in the floating-point format to an external apparatus via a transmission path.
   (2)

The transmission apparatus according to (1) above, in which the data in the floating-point format includes a 16-bit half-precision floating-point data.

(3)

The transmission apparatus according to (1) or (2) above, in which the conversion section sets a maximum displacement of the vibration signal to a predetermined value smaller than a maximum value of a range of a value determined by the number of bits of an exponent part of the data in the floating-point format, thereby converting the vibration signal into the data in the floating-point format.

(4)

The transmission apparatus according to (3) above, in which the predetermined value includes 1.

(5)

The transmission apparatus according to any one of (1) to (4) above, in which the transmission path includes an HDMI transmission path.

(6)

The transmission apparatus according to any one of (1) to (5) above, in which the transmission section uses a transmission signal structure for each block including a plurality of frames for an audio signal to transmit the data in the floating-point format.

(7)

The transmission apparatus according to (6) above, in which
the transmission signal structure includes a frame structure of an IEC 60958 standard, and
the transmission section disposes the data in the floating-point format in a region for an audio sample word or regions for the audio sample word and auxiliary sample bits and transmits the data in the floating-point format.
   (8)

The transmission apparatus according to (7) above, in which the data in the floating-point format is disposed in an order of a sign part, an exponent part, and a fraction part from a most significant bit side of the audio sample word without a space, in the region for the audio sample word or the regions for the audio sample word and auxiliary sample bits.

(9)

The transmission apparatus according to (8) above, in which the exponent part in the data in the floating-point format includes 5 bits and the fraction part includes 10 bits, 14 bits, or 18 bits.

(10)

The transmission apparatus according to any one of (6) to (9) above, in which a channel status provided in the transmission signal structure for each block includes information indicating that the data in the floating-point format is disposed in the region for the audio sample word or the regions for the audio sample word and the auxiliary sample bits.

(11)

The transmission apparatus according to (10) above, in which the channel status provided in the transmission signal structure for each block includes information indicating the number of bits of the data in the floating-point format disposed in the region for the audio sample word or the regions for the audio sample word and the auxiliary sample bit.

(12)

The transmission apparatus according to any one of (1) to (11) above, in which the transmission section applies, when a sign part of the data in the floating-point format indicates a negative sign, bit inversion processing to the exponent part, and then transmits the data in the floating-point format.

(13)

The transmission apparatus according to any one of (1) to (11) above, in which the transmission section applies, when a sign part of the data in the floating-point format indicates a negative sign, bit inversion processing to an exponent part and performs processing of converting a fraction part into a two's complement number, and then transmits the data in the floating-point format.

(14)

The transmission apparatus according to any one of (1) to (13) above, in which the vibration signal includes an audio signal.

(15)

The transmission apparatus according to any one of (1) to (13) above, in which the vibration signal includes a tactile vibration signal.

(16)

A reception apparatus including:
a reception section that receives, from an external apparatus via a transmission path, data in floating-point format obtained by converting a vibration signal; and
a processing section that processes the data in the floating-point format.
   (17)

The reception apparatus according to (16) above, in which the transmission path includes an HDMI transmission path.

(18)

The reception apparatus according to (16) or (17) above, in which the data in the floating-point format includes a 16-bit half-precision floating-point data.

(19)

The reception apparatus according to any one of (16) to (18) above, in which the reception section uses a transmission signal structure for each block including a plurality of frames for an audio signal to receive the data in the floating-point format.

(20)

A transception system,
in which a transmission apparatus and a reception apparatus are connected to each other via a transmission path,
the transmission apparatus includes
   a conversion section that converts a vibration signal into data in floating-point format, and
   a transmission section that transmits the data in the floating-point format to the reception apparatus via the transmission path, and
the reception apparatus includes
   a reception section that receives the data in the floating-point format from the transmission apparatus via the transmission path, and
   a processing section that processes the data in the floating-point format.

### REFERENCE SIGNS LIST

10, 20, 30: Transception system
100: AV amplifier
101: HDMI transmitter
102: ARC/eARC reception section
103: Audio processing section
104: Speaker system
200: Smart TV
201: HDMI receiver
202: Transmission processing section
203: ARC/eARC transmission section
300: HDMI cable
400: Media player
401: HDMI transmitter
402: Transmission processing section
500: AV amplifier
501: HDMI receiver
502: Audio processing section
503: Speaker system
600: HDMI cable
700: Television receiver
701: HDMI terminal
702: HDMI reception section
703: ARC/eARC transmission section
704: Audio transmission circuit
705: System controller
707: Digital broadcast reception circuit
708: Content reproduction circuit
709: Display section
710: Network interface
721: Reception antenna
722: BD player
723: Internet
800: Audio amplifier
801: HDMI terminal
802: HDMI transmission section
803: ARC/eARC reception section
804: Audio reception circuit
805: System controller
808: Audio reproduction circuit
809: Tactile vibration generation circuit
850: Speaker system
860: Tactile vibration system

1. A transmission apparatus comprising:
a conversion section that converts a vibration signal to data in floating-point format; and
a transmission section that transmits the data in the floating-point format to an external apparatus via a transmission path.

2. The transmission apparatus according to claim 1, wherein the data in the floating-point format includes a 16-bit half-precision floating-point data.

3. The transmission apparatus according to claim 1, wherein the conversion section sets a maximum displacement of the vibration signal to a predetermined value smaller than a maximum value of a range of a value determined by the number of bits of an exponent part of the data in the floating-point format, thereby converting the vibration signal into the data in the floating-point format.

4. The transmission apparatus according to claim 3, wherein the predetermined value includes 1.

5. The transmission apparatus according to claim 1, wherein the transmission path includes an HDMI transmission path.

6. The transmission apparatus according to claim 1, wherein the transmission section uses a transmission signal structure for each block including a plurality of frames for an audio signal to transmit the data in the floating-point format.

7. The transmission apparatus according to claim 6, wherein
the transmission signal structure includes a frame structure of an IEC 60958 standard, and
the transmission section disposes the data in the floating-point format in a region for an audio sample word or regions for the audio sample word and auxiliary sample bits and transmits the data in the floating-point format.

8. The transmission apparatus according to claim 7, wherein the data in the floating-point format is disposed in an order of a sign part, an exponent part, and a fraction part from a most significant bit side of the audio sample word without a space, in the region for the audio sample word or the regions for the audio sample word and auxiliary sample bits.

9. The transmission apparatus according to claim 8, wherein the exponent part in the data in the floating-point format includes 5 bits and the fraction part includes 10 bits, 14 bits, or 18 bits.

10. The transmission apparatus according to claim 6, wherein a channel status provided in the transmission signal structure for each block includes information indicating that the data in the floating-point format is disposed in the region for the audio sample word or the regions for the audio sample word and the auxiliary sample bits.

11. The transmission apparatus according to claim 10, wherein the channel status provided in the transmission signal structure for each block includes information indicating the number of bits of the data in the floating-point format disposed in the region for the audio sample word or the regions for the audio sample word and the auxiliary sample bit.

12. The transmission apparatus according to claim 1, wherein the transmission section applies, when a sign part of the data in the floating-point format indicates a negative sign, bit inversion processing to the exponent part, and then transmits the data in the floating-point format.

13. The transmission apparatus according to claim 1, wherein the transmission section applies, when a sign part of the data in the floating-point format indicates a negative sign, bit inversion processing to an exponent part and performs processing of converting a fraction part into a two's complement number, and then transmits the data in the floating-point format.

14. The transmission apparatus according to claim 1, wherein the vibration signal includes an audio signal.

15. The transmission apparatus according to claim 1, wherein the vibration signal includes a tactile vibration signal.

16. A reception apparatus comprising:
a reception section that receives, from an external apparatus via a transmission path, data in floating-point format obtained by converting a vibration signal; and
a processing section that processes the data in the floating-point format.

17. The reception apparatus according to claim 16, wherein the transmission path includes an HDMI transmission path.

18. The reception apparatus according to claim 16, wherein the data in the floating-point format includes a 16-bit half-precision floating-point data.

19. The reception apparatus according to claim 16, wherein the reception section uses a transmission signal structure for each block including a plurality of frames for an audio signal to receive the data in the floating-point format.

20. A transception system,
wherein a transmission apparatus and a reception apparatus are connected to each other via a transmission path,
the transmission apparatus includes
a conversion section that converts a vibration signal into data in floating-point format, and
a transmission section that transmits the data in the floating-point format to the reception apparatus via the transmission path, and
the reception apparatus includes
a reception section that receives the data in the floating-point format from the transmission apparatus via the transmission path, and
a processing section that processes the data in the floating-point format.
